(19) United States
(12) Patent Application Publication
(10) Pub. No.: US 2023/0320086 A1
(43) Pub. Date: Oct. 5, 2023

(54) SEMICONDUCTOR MEMORY DEVICE AND MANUFACTURING METHOD OF THE SEMICONDUCTOR MEMORY DEVICE

(71) Applicant: SK hynix Inc., Icheon-si Gyeonggi-do (KR)

(72) Inventors: Kun Young LEE, Icheon-si Gyeonggi-do (KR); Sang Soo KIM, Icheon-si Gyeonggi-do (KR); Sang Wan JIN, Icheon-si Gyeonggi-do (KR)

(73) Assignee: SK hynix Inc., Icheon-si Gyeonggi-do (KR)

(21) Appl. No.: 17/958,735

(22) Filed: Oct. 3, 2022

(30) Foreign Application Priority Data
Mar. 31, 2022 (KR) 10-2022-0040013

(51) Int. Cl. H01L 27/11556; H01L 27/11519; H01L 27/11565; H01L 27/11582

(52) U.S. Cl. CPC H01L 27/11556; H01L 27/11519; H01L 27/11565; H01L 27/11582

(57) ABSTRACT

A semiconductor memory device includes: a first gate stack structure including first interlayer insulating layers and first conductive layers, which are alternately stacked in a vertical direction; a dummy vertical channel penetrating the first gate stack structure; lower vertical channels penetrating the first gate stack structure at both sides of the dummy vertical channel; a second gate stack structure including second interlayer insulating layers and second conductive layers, which are alternately stacked in the vertical direction on the first gate stack structure; a first select line isolation structure partially penetrating the second gate stack structure; upper vertical channels connected to the lower vertical channels while penetrating the second gate stack structure; and a second select line isolation structure overlapping with the dummy vertical channel in the vertical direction, the second select line isolation structure penetrating a portion of the second gate stack structure.

### CROSS-REFERENCE TO RELATED APPLICATION

The present application claims priority under 35 U.S.C. § 119(a) to Korean patent application number 10-2022-0040013, filed on Mar. 31, 2022, in the Korean Intellectual Property Office, the entire disclosure of which is incorporated herein by reference.

### BACKGROUND

### 1. Technical Field

The present disclosure generally relates to a semiconductor memory device and a manufacturing method of the semiconductor memory device, and more particularly, to a three-dimensional semiconductor memory device and a manufacturing method of the three-dimensional semiconductor memory device.

### 2. Related Art

A nonvolatile memory device is a memory device in which stored data is retained as it is even when the supply of power is interrupted. As the improvement of the degree of integration of two-dimensional nonvolatile memory devices in which memory cells are formed in the form of a single layer over a substrate reaches the limit, there has recently been proposed a three-dimensional nonvolatile memory device in which memory cells are stacked vertically over a substrate.

The three-dimensional nonvolatile memory device includes insulating layers and gate electrodes, which are alternately stacked, and channel layers penetrating the insulating layers and the gate electrodes, and memory cells are stacked along the channel layers, Various structures and various manufacturing methods have been developed to improve the operational reliability of such a nonvolatile memory device having a three-dimensional structure.

### SUMMARY

In accordance with an aspect of the present disclosure, there is provided a semiconductor memory device including: a first gate stack structure including first interlayer insulating layers and first conductive layers, which are alternately stacked in a vertical direction; a dummy vertical channel penetrating the first gate stack structure; lower vertical channels penetrating the first gate stack structure at both sides of the dummy vertical channel; a second gate stack structure including second interlayer insulating layers and second conductive layers, which are alternately stacked in the vertical direction on the first gate stack structure; a first select line isolation structure partially penetrating the second gate stack structure; upper vertical channels connected to the lower vertical channels while penetrating the second gate stack structure; and a second select line isolation structure overlapping with the dummy vertical channel in the vertical direction, the second select line isolation structure penetrating a portion of the second gate stack structure.

In accordance with another aspect of the present disclosure, there is provided a semiconductor memory device including: a first gate stack structure including first interlayer insulating layers and first conductive layers, which are alternately stacked in a vertical direction; a dummy vertical channel and lower vertical channels, penetrating the first gate stack structure; an etch stop layer disposed over the dummy vertical channel and directly on the dummy vertical channel; a lower memory layer surrounding the lower vertical channels; a second gate stack structure including second interlayer insulating layers and second conductive layers, which are alternately stacked in the vertical direction on the first gate stack structure; an upper insulating layer disposed on the second gate stack structure; a first select line isolation structure penetrating the upper insulating layer and a portion of the second gate stack structure; and a second select line isolation structure penetrating the upper insulating layer and the second gate stack structure, the second select line isolation structure being in contact with the etch stop layer.

In accordance with still another aspect of the present disclosure, there is provided a method of manufacturing a semiconductor memory device, the method including: forming a first stack structure; forming a dummy vertical channel and lower vertical channels, which penetrate the first stack structure; forming a second stack structure on the first stack structure; forming first and second select line isolation structures penetrating portions of the second stack structure; and forming upper vertical channels connected to the lower vertical channels while penetrating the second stack structure, wherein the second select line isolation structure is formed longer than the first select line isolation structure, and wherein each of the first stack structure and the second stack structure includes a plurality of first material layers and a plurality of second material layers, which are alternately stacked in a vertical direction.

In accordance with still another aspect of the present disclosure, there is provided a method of manufacturing a semiconductor memory device, the method including: forming a first stack structure; forming channel holes penetrating the first stack structure; forming lower memory layers along surfaces of the channel holes; forming a dummy vertical channel and lower vertical channels inside the channel holes; forming an insulating layer inside each of the lower memory layers; forming a second stack structure on the first stack structure; forming upper vertical channels connected to the lower vertical channels while penetrating the second stack structure; and forming a first select line isolation structure and a second select line isolation structure, which penetrate portions of the second stack structure, wherein each of the lower memory layers includes a blocking insulating layer extending along a sidewall of a channel hole corresponding thereto among the channel holes, a data storage layer extending along a sidewall of the blocking insulating layer, and a tunnel insulating layer extending along a sidewall of the data storage layer, and wherein the insulating layer is disposed between the blocking insulating layer and the data storage layer, and covers the data storage layer.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

Embodiments provide a semiconductor memory device and a s manufacturing method of the semiconductor memory device, which can facilitate a manufacturing process of connecting an upper vertical channel and a lower vertical channel to each other and have a stable structure and improved characteristics.

FIG. 1 is a block diagram schematically illustrating a semiconductor memory device in accordance with an embodiment of the present disclosure,

FIG. 2 is a plan view illustrating a layout of a semiconductor memory device in accordance with an embodiment of the present disclosure.

FIG. 3 is a sectional view illustrating a structure of a semiconductor memory device in accordance with an embodiment of the present disclosure,

FIGS. 4A, 48, 4C, 4D, and 4E are sectional views illustrating a manufacturing method of a semiconductor memory device in accordance with an embodiment of the present disclosure.

FIGS. 5A, 58, 5C, and 5D are sectional views illustrating a manufacturing method of a semiconductor memory device in accordance with an embodiment of the present disclosure,

FIGS. 6A, 68, 6C, 6D, 6E, 6F, 6G, 6H, and 6I are sectional views illustrating a manufacturing method of a semiconductor memory device in accordance with an embodiment of the present disclosure.

FIGS. 7A, 76, 7C, and 7D are sectional views illustrating a manufacturing method of a semiconductor memory device in accordance with an embodiment of the present disclosure.

FIG. 8 is a block diagram illustrating a configuration of a memory system in accordance with an embodiment of the present disclosure.

FIG. 9 is a block diagram illustrating a configuration of a computing system in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

It will be understood that, although the terms “first,” “second,” etc, may be used herein to describe various elements, these elements should not be limited by these terms. These terms are only used to distinguish one element from another element. Thus, a “first” element discussed below could also be termed a “second” element without departing from the teachings of the present disclosure. It will be understood that when an element or layer etc, is referred to as being “on,” “connected to,” “in contact,” or “coupled to” another element or layer etc., it can be directly on, connected, in contact or coupled to the other element or layer etc., or intervening elements or layers etc., may be present. In contrast, when an element or layer etc., is referred to as being “directly on,” “directly connected to” “in direct contact with” or “directly coupled to” another element or layer etc., there are no intervening elements or layers present. In some embodiments, it will be understood that when a structure or element etc., is referred to as penetrating another structure or element etc., it can partially penetrate the other structure or element etc., by extending into a portion of the other structure or element etc., or completely penetrate the other structure or element etc., by passing through the entire structure or element etc.

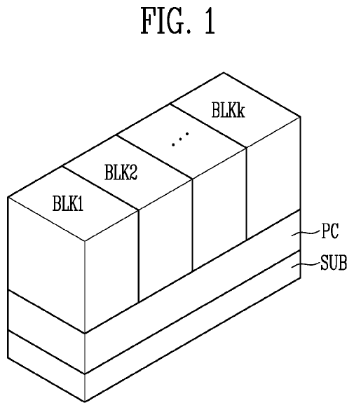

FIG. 1 is a block diagram schematically illustrating a semiconductor memory device in accordance with an embodiment of the present disclosure.

Referring to FIG. 1, the semiconductor memory device may include a peripheral circuit structure PC and memory blocks BLK1 to BLKk (k is a natural number greater than 2), which are disposed on a substrate SUB.

The substrate SUB may be a single crystalline semiconductor layer. For example, the substrate SUB may be a bulk silicon substrate, a silicon on insulator substrate, a germanium substrate, a germanium on insulator substrate, a silicon-germanium substrate, or an epitaxial thin film formed through a selective epitaxial growth process.

The peripheral circuit structure PC may include a row decoder, a column decoder, a page buffer, a control circuit, and the like, which constitute a circuit for controlling operations of the memory blocks BLK1 to BLKk. For example, the peripheral circuit structure PC may include an NMOS transistor, a PMOS transistor, a resistor, a capacitor, and the like, which are electrically connected to the memory blocks BLEU to BLKk. The peripheral circuit structure PC may be disposed between the substrate SUB and the memory blocks BLK1 to BLKk. However, the present disclosure does not exclude an embodiment in which the peripheral circuit structure PC extends to another region of the substrate SUB, which does not overlap with the memory blocks BLK1 to BLKk.

Each of the memory blocks BLK1 to BLKk may include impurity doping regions, bit lines, cell strings electrically connected to the impurity doping regions and the bit lines, word lines electrically connected to the cell strings, and select lines electrically connected to the cell strings. Each of the cell strings may include memory cells and select transistors, which are connected in series by a channel layer. Each of the select lines may be used as a gate electrode of a select transistor corresponding thereto, and each of the word lines may be used as a gate electrode of a memory cell corresponding thereto.

In order to increase an arrangement density of a plurality of cell strings, a plurality of cell strings may be connected to the same bit line, and share the same word line. According to this structure, two or more cell strings may share the same word line, and be connected to the same bit line. In order to individually control the two or more cell strings, the two or more cell strings may be individually connected to two or more select lines isolated from each other. In an embodiment, the number of cell strings which share the same word line and the same bit line is increased, and the arrangement density of cell strings is decreased, so that the degree of integration of the semiconductor memory device can be improved. The select lines may be isolated from each other by a select line isolation structure.

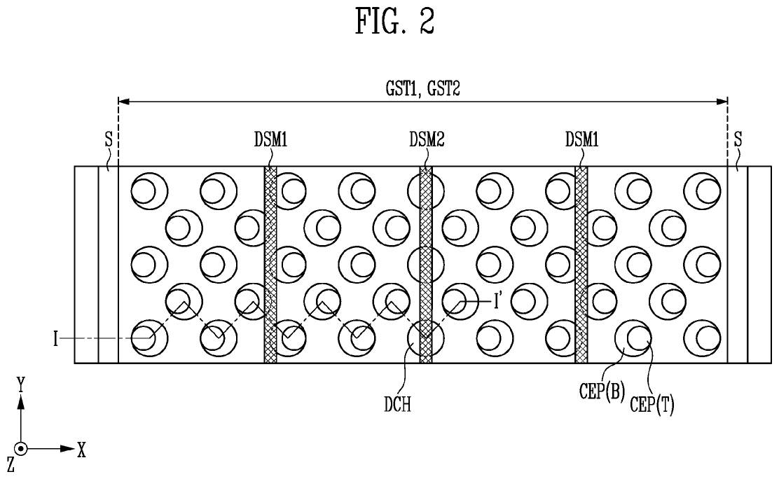

FIG. 2 is a plan view illustrating a layout of a semiconductor memory device in accordance with an embodiment of the present disclosure. Hereinafter, a first direction X, a second direction Y, and a third direction Z may be defined as directions in which axes intersecting one another face. In an embodiment, the first direction X, the second direction Y, and the third direction Z may be defined as an X axis, a Y axis, and a Z axis of an XYZ coordinate system.

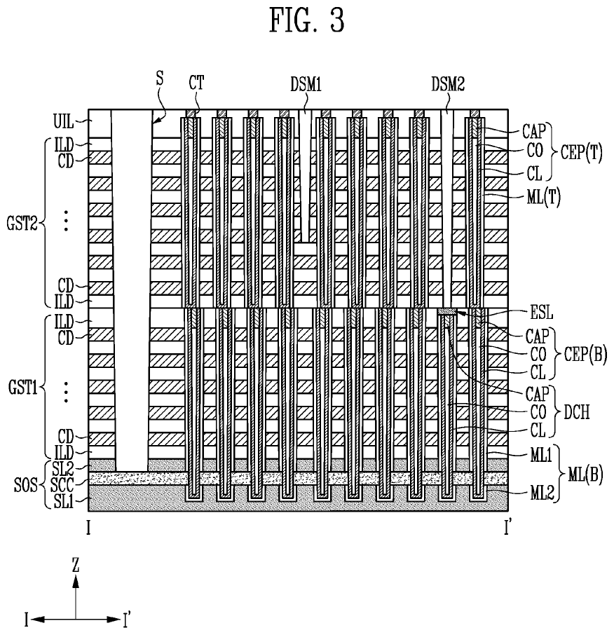

Referring to FIG. 2, the semiconductor memory device in accordance with the embodiment of the present disclosure may include a first gate stack structure GST1 and a second gate stack structure GST2. Each of the first gate stack structure GST1 and the second gate stack structure GST2 may include a plurality of layers which extend in the first direction X and the second direction Y, and are stacked in the third direction Z. The plurality of layers may be interlayer insulating layers ILD and conductive layers CD, which are shown in FIG. 3. The first gate stack structure GST1 and the second gate stack structure GST2 may be arranged in the third direction Z.

Each of the first gate stack structure GST1 and the second gate stack structure GST2 may be partitioned by slits S. The second gate stack structure GST2 may include layers isolated from each other in the first direction X by select line isolation structures DSM1 and DSM2. The select line isolation structures DSM1 and DSM2 may include first select line isolation structures DSM1 and a second select line isolation structure DSM2. Each of the first select line isolation structures DSM1 may be disposed closer to the slit S than the second select line isolation structure DSM2, The second select line isolation structure DSM2 may be disposed between first select line isolation structures DSM1 adjacent to each other in the first direction X. In other words, the first select line isolation structures DSM1 may be disposed at both sides of the second select line isolation structure DSM2.

The slit S may extend in the third direction Z along sidewalls of the first gate stack structure GST1 and the second gate stack structure GST2. An insulating material may be disposed inside the slit S, or an insulating material and a conductive vertical contact penetrating the insulating material may be formed inside the slit S. The conductive vertical contact may be insulated from a conductive layer of each of the first gate stack structure GST1 and the second gate stack structure GST2 by the insulating material. The select line isolation structures DSM1 and DSM2 may be disposed between slits S adjacent to each other in the first direction X. The select line isolation structures DSM1 and DSM2 may overlap with the first gate stack structure GST1. In other words, a depth of the select line isolation structures DSM1 and DSM2 may be controlled as a depth to which the select line isolation structures DSM1 and DSM2 do not penetrate the first gate stack structure GST1.

Each of the slit S and the select line isolation structures DSM1 and DSM2 may extend in the second direction Y. Each of the first gate stack structure GST1 and the second gate stack structure GST2 may be penetrated by a plurality of cell vertical channels CEP. The plurality of cell vertical channels CEP may be disposed at both sides of each of the select line isolation structures DSM1 and DSM2. Each of the cell vertical channels CEP may extend in the third direction Z. A plurality of cell vertical channels CEP disposed between slits S adjacent to each other may be divided into a plurality of channel groups. At least one uppermost conductive layer among a plurality of conductive layers CD of a second gate stack structure GST2 shown in FIG. 3 may be divided into a plurality of lines by the select line isolation structures DSM1 and DSM2, and each of the lines may be used as a drain select line. The plurality of channel groups may be individually controlled respectively by the plurality of lines configured with the uppermost conductive line. The first gate stack structure GST1 may be penetrated by a plurality of dummy vertical channels DCH. The plurality of dummy vertical channels DCH may be arranged in a line in the second direction Y. The second select line isolation structure DSM2 may overlap with the plurality of dummy vertical channels DCH. A portion of the second gate stack structure GST2, which is adjacent to the second select line isolation structure DSM2, may overlap with each dummy vertical channel DCH.

A width of each of the select line isolation structures DSM1 and DSM2 may be formed different from a width of each slit S. More specifically, each of the select line isolation structures DSM1 and DSM2 may be formed narrower in the first direction X than each slit S. The second select line isolation structure DSM2 may be formed narrower in the first direction X than each dummy vertical channel DCH.

Each cell vertical channel CEP may include a lower vertical channel CEP(B) penetrating the first gate stack structure GST1 and an upper vertical channel CEP(T) penetrating the second gate stack structure GST2. The upper vertical channel CEP(T) may overlap with the lower vertical channel CEP(B), and be connected to the lower vertical channel CEP(B), The dummy vertical channel DCH may be formed in the same structure as the lower vertical channel CEP(B).

At both sides of the plurality of dummy vertical channels DCH, a plurality of lower vertical channels CEP(B) may be disposed in zigzag. However, the present disclosure is not limited thereto. In an embodiment, at both sides of the plurality of dummy vertical channels DCH, the plurality of lower vertical channels CEP(B) may be arranged side by side in the first direction X and the second direction Y. An arrangement of plurality of upper vertical channels CEP(T) may be designed according to the arrangement of the plurality of lower vertical channels CEP(B).

FIG. 3 is a sectional view illustrating a structure of a semiconductor memory device in accordance with an embodiment of the present disclosure, FIG. 3 illustrates a sectional view of the semiconductor memory device taken along line I-I′ shown in FIG. 2.

Referring to FIG. 3, the semiconductor memory device in accordance with the embodiment of the present disclosure may include a source structure SOS. The source structure SOS may have the shape of a plate expanding along a plane defined by the first direction X and the second direction Y. The first direction X and the second direction Y may intersect each other. In an example, the first direction X and the second direction Y may be orthogonal to each other.

In an embodiment, the source structure SOS may be disposed on a substrate which physically supports the source structure SOS, In an example, the substrate may be a semiconductor substrate or an insulator substrate.

In an embodiment, a peripheral circuit structure including transistors and lines may be disposed between the source structure SOS and the substrate.

The source structure SOS may include a first source layer SL1, a source channel connection layer SCC, and a second source layer SL2. The first source layer SL1, the source channel connection layer SCC, and the second source layer SL2 may be stacked in the third direction Z. The third direction Z may intersect the first direction X and the second direction Y. In an example, the third direction Z may be orthogonal to the first direction X and the second direction Y, In an embodiment, the third direction Z may be referred to as a vertical direction.

The first source layer SL1, the source channel connection layer SCC, and the second source layer SL2 may include the same material. The first source layer SL1, the source channel connection layer SCC, and the second source layer SL2 may include a semiconductor material. In an embodiment, the first source layer SL1, the source channel connection layer SCC, and the second source layer SL2 may include doped poly-silicon. The source channel connection layer SCC may be disposed in various forms. A conductivity type impurity doped in each of the first source layer SL1, the source channel connection layer SCC, and the second source layer SL2 may be at least one of an n-type and a p-type. The first source layer SL1, the source channel connection layer SCC, and the second source layer SL2 may include the same conductivity type impurity or include different conductivity type impurities.

A first gate stack structure GST1 and a second gate stack structure GST2 may be stacked on the source structure SOS in the third direction Z. Each of the first gate stack structure GST1 and the second gate stack structure GST2 may include interlayer insulating layers ILD and conductive layers CD, which are alternately stacked in the third direction Z.

The interlayer insulating layers ILD of the first gate stack structure GST1 and the second gate stack structure GST2 may include various insulating materials. In an embodiment, the interlayer insulating layers ILD may include oxide. The conductive layers CD of the first gate stack structure GST1 and the second gate stack structure GST2 may include at least one of a doped silicon layer; a metal silicide layer, tungsten, nickel, and cobalt. Each of the conductive layers CD may be used as a word line connected to a memory cell or a select line connected to a select transistor. A lowermost conductive layer adjacent to the source structure SOS among the conductive layers CD may be used as a source select line. An uppermost conductive layer spaced most apart from the source structure among the conductive layers CD may be used as a drain select line.

A lower vertical channel CEP(B) and a dummy vertical channel DCH may penetrate the first gate stack structure GST1, the second source layer SL2, the source channel connection layer SCC, and the first source layer SL1, The lower vertical channel CEP(B) and the dummy vertical channel DCH may penetrate the interlayer insulating layers ILD and the conductive layers CD of the first gate stack structure GST1. The lower vertical channel CEP(B) and the dummy vertical channel DCH may extend in the third direction Z. A lowermost portion of each of the lower vertical channel CEP(B) and the dummy vertical channel DCH may be disposed in the first source layer SL1.

Each of the lower vertical channel CEP(B) and the dummy vertical channel DCH may be surrounded by a lower memory layer ML(B). The lower memory layer ML(B) may include a first memory layer ML1 disposed between each of the lower vertical channel CEP(B) and the dummy vertical channel DCH and the first gate stack structure GST1. In an embodiment, the first memory layer ML1 may surround a sidewall of each of the lower vertical channel CEP(B) and the dummy vertical channel DCH. The lower memory layer ML(B) may further include a second memory layer ML2 disposed between each of the lower vertical channel CEP(B) and the dummy vertical channel DCH and the first source layer SL1. The source channel connection layer SCC may extend between the first memory layer ML1 and the second memory layer ML2, and be connected to each of the lower vertical channel CEP(B) and the dummy vertical channel DCH.

An upper vertical channel CEP(T) may penetrate the second gate stack structure GST2. The upper vertical channel CEP(T) may extend in the third direction Z, The upper vertical channel CEP(T) may penetrate the interlayer insulating layers ILD and the conductive layers CD of the second gate stack structure GST2. The upper vertical channel CEP(T) may penetrate a lowermost interlayer insulating layer ILD in the second gate stack structure GST2.

A sidewall of the upper vertical channel CEP(T) may be surrounded by an upper memory layer ML(T). The upper memory layer ML(T) may be disposed between the upper vertical channel CEP(T) and the second gate stack structure GST2. The upper vertical channel CEP(T) may be connected to the lower vertical channel CEP(B).

Each of the dummy vertical channel DCH, the lower vertical channel CEP(B), and the upper vertical channel CEP(T) may include a channel layer CL, a capping pattern CAP, and a core pillar CO. The core pillar CO and the capping pattern CAP may be disposed in a central region of each of the dummy vertical channel DCH, the lower vertical channel CEP(B), and the upper vertical channel CEP(T). The channel layer CL may extend in the third direction Z along a sidewall of the core pillar CO and a side all of the capping pattern CAP. The channel layer CL may be configured with silicon, germanium, or a combination thereof, and be used as a channel region of a cell string. In an embodiment, the channel layer CL may include undoped silicon. The capping pattern CAP may be configured with silicon, germanium, or a combination thereof, including a conductivity type dopant for junctions. In an embodiment, the capping pattern CAP may be configured with n-type doped silicon.

A channel layer CL of the lower vertical channel CEP(B) may penetrate the first gate stack structure GST1, the second source layer SL2, the source channel connection layer SCC, and the first source layer SL1. The channel layer CL of the lower vertical channel CEP(B) may be in contact with the source channel connection layer SCC. The channel layer of the lower vertical channel CEP(B) may be electrically connected to the source structure SOS through the source channel connection layer SCC.

A slit S may be disposed, which penetrates the second gate stack structure GST2, the first gate stack structure GST1, and the second source layer SL2.

First and second select line isolation structures DSM1 and DSM2 may be disposed, which penetrate portions of the second gate stack structure GST2. Depths of the first select line isolation structure DSM1 and the second select line isolation structure DSM2 in the third direction Z may be the same or be different from each other. The second select line isolation structure DSM2 may overlap with a dummy vertical channel DCH of the first gate stack structure GST1, which corresponds thereto in the third direction Z. The second select line isolation structure DSM2 may extend to be in contact with the dummy vertical channel DCH, or be disposed at a position spaced apart from the dummy vertical channel DCII in the third direction Z.

In an embodiment, the dummy vertical channel DCH may be formed in the same structure as the lower vertical channel CEP(B). In another embodiment, a capping pattern CAP of the dummy vertical channel DCH may remain at a height lower in the third direction Z than a height of a capping pattern CAP of the lower vertical channel CEP(B). The dummy vertical channel DCH may further include an etch stop layer ESL. The etch stop layer ESL of the dummy vertical channel DCH may be configured with oxide of the capping pattern CAP.

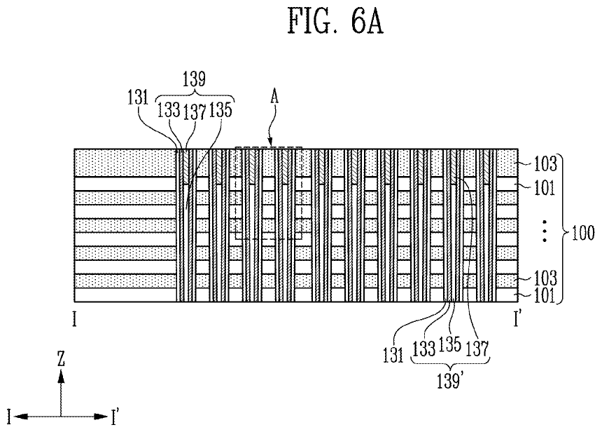

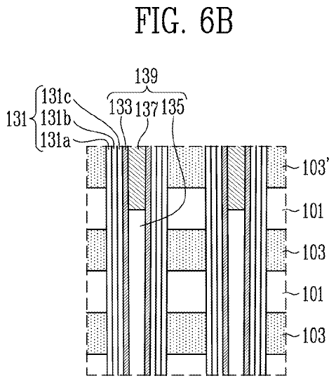

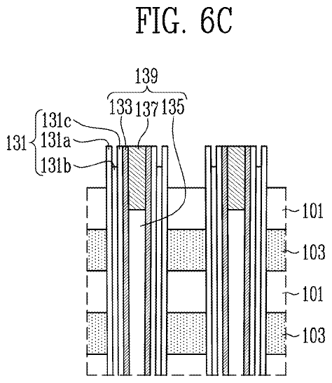

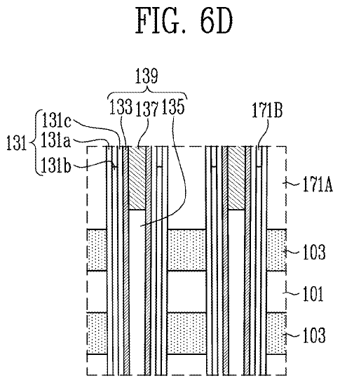

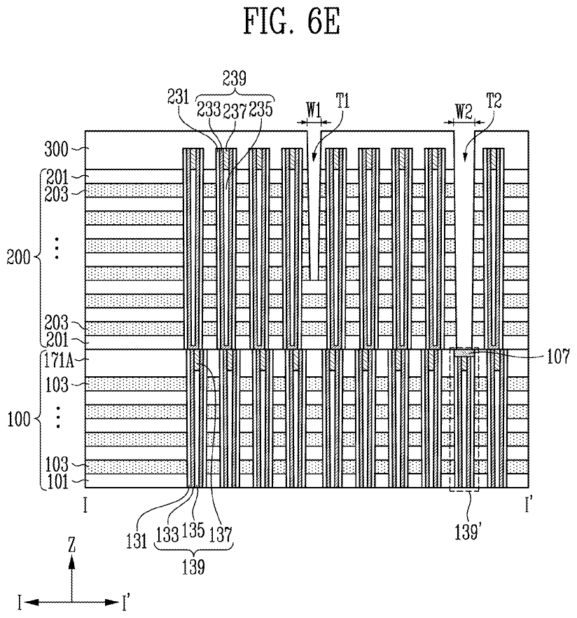

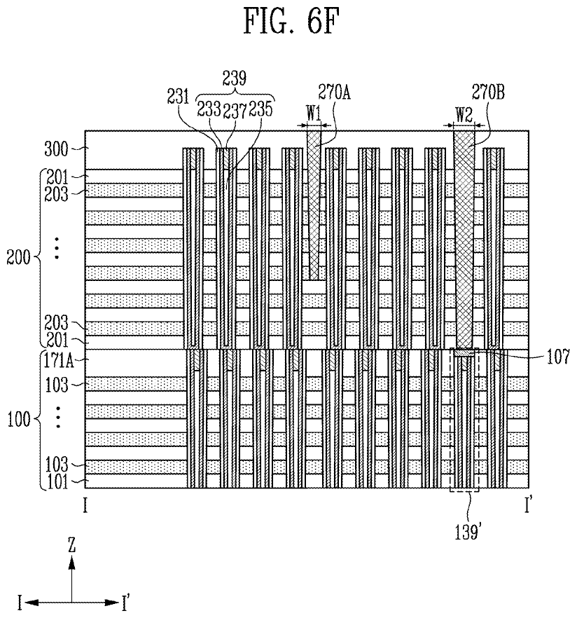

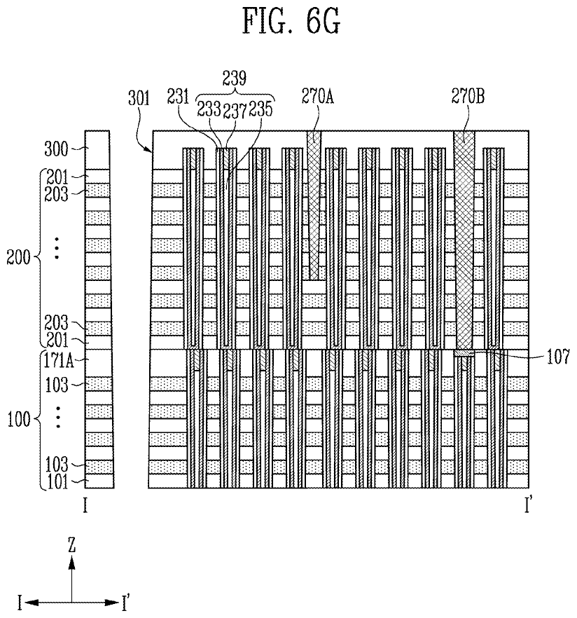

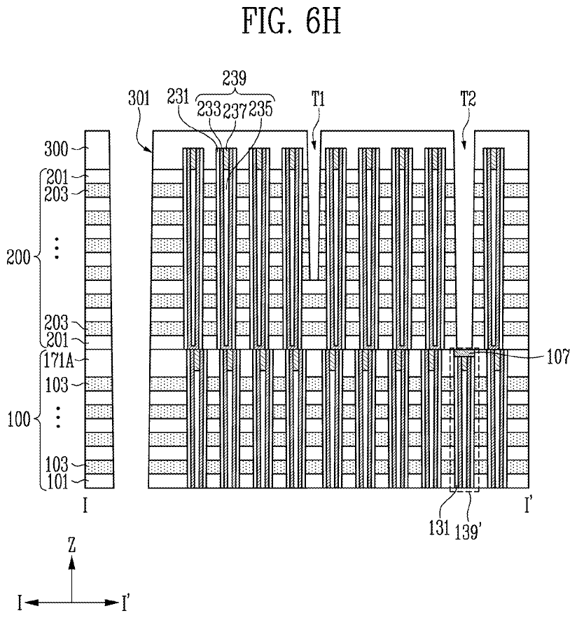

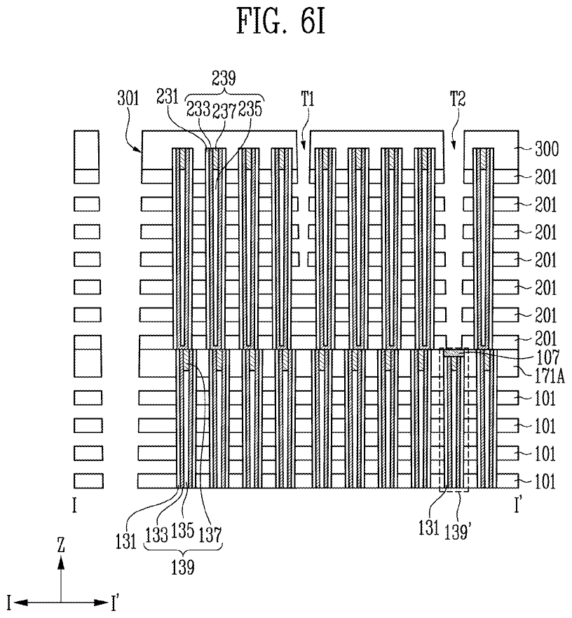

Each of the lower memory layer ML(B) and the upper memory layer ML(T) may include a blocking insulating layer extending along a surface of the channel layer CL, a data storage layer between the blocking insulating layer and the channel layer CL, and a tunnel insulating layer between the data storage layer and the channel layer CL. The blocking insulating layer, the data storage layer, and the tunnel insulating layer will be described in detail later with reference to FIG. 6B.

The upper vertical channel CEP(T) may include a protrusion part further protruding in the third direction Z than the second gate stack structure GST2. The protrusion part of the upper vertical channel CEP(T) may be covered by an upper insulating layer UIL. The upper insulating layer UIL may be disposed on the second gate stack structure GST2, and be penetrated by the slit S.

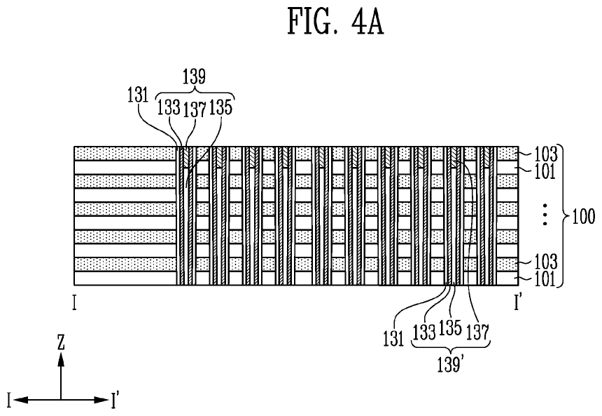

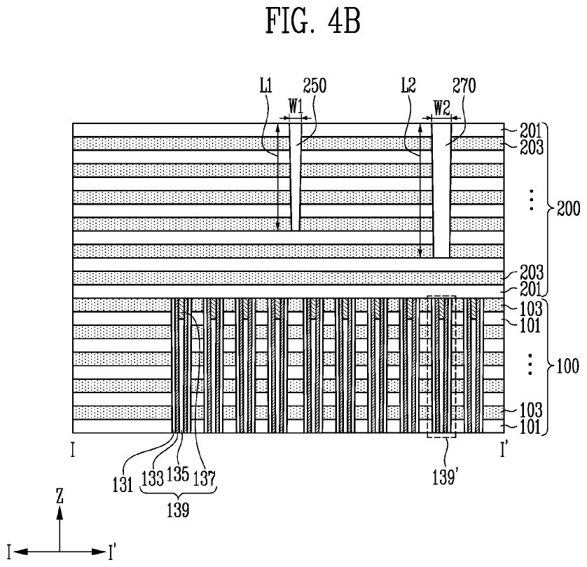

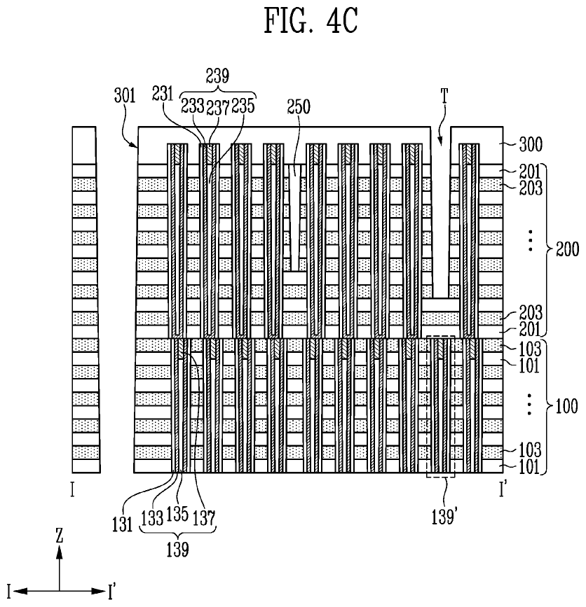

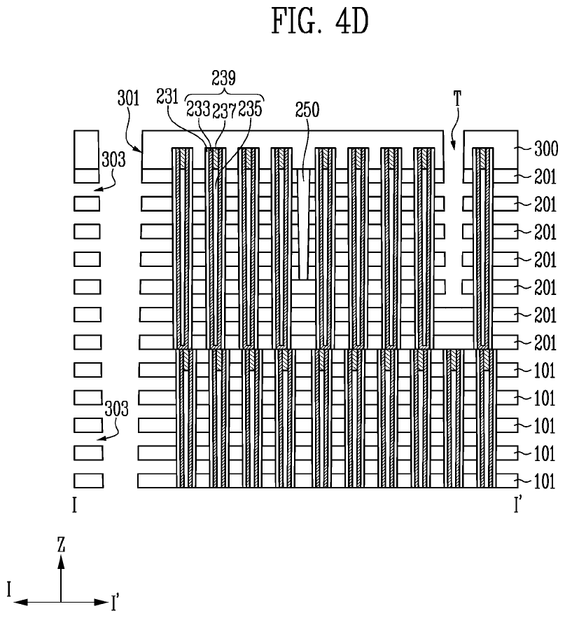

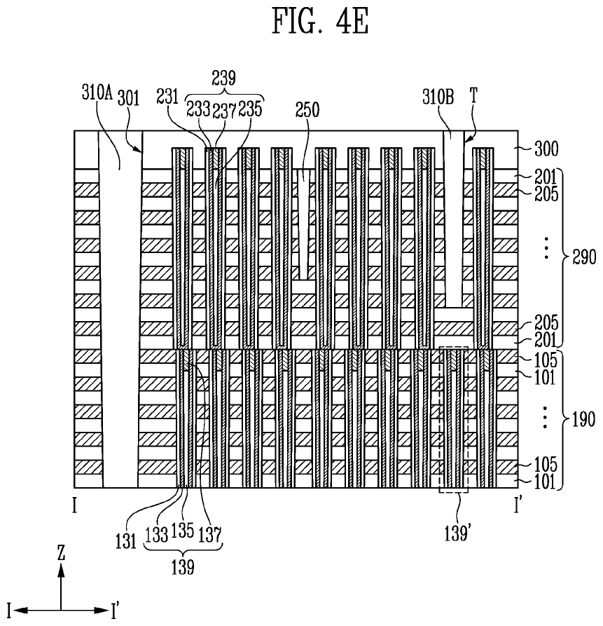

FIGS. 4A to 4E are sectional views illustrating a manufacturing method of a semiconductor memory device in accordance with an embodiment of the present disclosure. FIGS. 4A to 4E are process sectional views taken along the line shown in FIG. 2.

Referring to FIG. 4A, a first stack structure 100 may be formed. First material layers 101 and second material layers 103 may be alternately stacked in a vertical direction, thereby forming the first stack structure 100, The first stack structure 100 may be formed on a doped semiconductor layer (not shown). The first material layer 101 may be formed of a material different from a material of the second material layer 103, and the first material layer 101 and the second material layer 103 may have different etch rates. In an embodiment, the first material layer 101 may be formed as a silicon oxide layer, and the second material layer 103 may be formed as a silicon nitride layer. In an embodiment, an uppermost portion of the first stack structure 100 may include a second material layer 103.

Lower memory layers 131, lower vertical channels 139, and a dummy vertical channel 139′ may be formed, which penetrate the first stack structure 100. In an embodiment, in order to form the lower memory layers 131, the lower vertical channels 139, and the dummy vertical channel 139′, a channel hole penetrating the first stack structure 100 may be formed, the lower memory layer 131 may be formed along a sidewall of the channel hole, and then a channel layer 133 may be formed along a sidewall of the lower memory layer 131. Subsequently, a core pillar 135 and a capping pattern 137 may be formed inside a central region of the channel hole. The capping patter 137 may be formed on the core pillar 135. The lower memory layer 131 may be formed in a liner shape. The channel layer 133 may include a semiconductor layer used as a channel region. For example, the channel layer 133 may include silicon. In an embodiment, the channel layer 133 may be formed in a liner shape, and the central region of the channel hole may include a portion which is not filled with the channel layer. The core pillar 135 may include oxide, and the capping pattern 137 may include a conductivity type dopant. The conductivity type dopant may include an n-type dopant for junctions. The conductivity dopant may include a counter-doped p-type dopant.

Through the above-described process, a sidewall of each of the lower vertical channel 139 and the dummy vertical channel 139′ may be surrounded by the lower memory layer 131, and each of the lower vertical channel 139 and the dummy vertical channel 139′ may include a channel layer 133, a core pillar 135, and a capping pattern 137.

Referring to FIG. 4B, a second stack structure 200 may be formed on the first stack structure 100. The second stack structure 200 may include first material layers 201 and second material layers 203, which are alternately stacked in the vertical direction on the first stack structure 100. In an embodiment, the first material layers 101 of the first stack structure 100 may include the same material as the first materials 201 of the second stack structure 200, and the second material layers 103 of the first stack structure 100 may include the same material as the second material layers 203 of the second stack structure 200.

A first select line isolation structure 250 and a preliminary select line isolation structure 270 may be formed by etching portions of the second stack structure 200. In an embodiment, the first select line isolation structure 250 and the preliminary select line isolation structure 270 may be simultaneously formed. In an embodiment, widths of the first select line isolation structure 250 and the preliminary select line isolation structure 270 may be different from each other, and lengths of the first select line isolation structure 250 and the preliminary select line isolation structure 270 may be different from each other. For example, a second width W2 of the preliminary select line isolation structure 270 may be wider than a first width W1 of the first select line isolation structure 250. A second length L2 of the preliminary select line isolation structure 270 may be longer than a first length L1 of the first select line isolation structure 250. The preliminary select line isolation structure 270 may overlap with a dummy vertical channel 139′. In other words, the dummy vertical channel 139′ and the preliminary select line isolation structure 270 may be disposed in a line in the vertical direction. The first select line isolation structure 250 and the preliminary select line isolation structure 270 may be configured with an insulating material.

Referring to FIG. 4C, upper memory layers 231 and upper vertical channels 239 may be formed, which penetrate the second stack structure 200, In order to form the upper memory layer 231 and the upper vertical channels 239, a channel hole penetrating the second stack structure 200 may be formed, the upper memory layer 231 may be formed along a sidewall of the channel hole, and then a channel layer 233 may be formed along a sidewall of the upper memory layer 231, Subsequently, a core pillar 235 and a capping pattern 237 may be formed in a central region of the channel hole. The capping pattern 237 may be formed on the top of the core pillar 235.

Through the above-described process, a sidewall of the upper vertical channel 239 may be surrounded by the upper memory layer 231, The upper vertical channel 239 may include the channel layer 233, the core pillar 235, and the capping pattern 237.

The upper vertical channels 239 may be connected to the lower vertical channels 139. In an embodiment, the channel layer 233 of each of the upper vertical channels 239 may be in contact with the capping pattern 137 of each of the lower vertical channels 139. The upper vertical channel 239 and the lower vertical channel 139 may be disposed in a line in the third direction Z as the vertical direction, and be electrically connected to each other. The lower vertical channels 139 do not overlap with the dummy vertical channel 139′, and may be disposed at both sides of the dummy vertical channel 139′.

Subsequently, a mask layer (not shown) may be removed, which is used as an etch barrier while the channel hole penetrating the second stack structure 200 is formed, Subsequently, an upper insulating layer 300 may be formed, which covers the upper vertical channels 239, the preliminary select line isolation structure 270 shown in FIG. 4B, and the second stack structure 200. In an embodiment, the upper insulating layer 300 may include oxide.

Subsequently, a preliminary trench may be formed, which penetrates the upper insulating layer 300 and exposes the preliminary select line isolation structure 270 shown in FIG. 4B. Subsequently, the preliminary select line isolation structure 270 shown in FIG. 4B may be removed through the preliminary trench. Accordingly, a trench T may be defined, which penetrates the upper insulating layer 300 and penetrates a portion of the second stack structure 200. The trench T may overlap with the dummy vertical channel 139′.

Subsequently, a slit 301 may be formed. The slit 301 may be formed while penetrating the upper insulating layer 300, the second stack structure 200, and the first stack structure 100.

The process of forming the slit 301 and the preliminary trench is not limited to the above-described embodiment, and the preliminary trench may be formed by using the process of forming the slit 301.

Referring to FIG. 4D, the second material layers 103 and 203 in the first stack structure 100 and the second stack structure 200, which are shown in FIG. 4C, may be selectively removed through the slit 301 and the trench T. Therefore, horizontal spaces 303 may be opened between the first material layers 101 and 201 adjacent to each other in the third direction Z.

Referring to FIG. 4E, the horizontal spaces 303 shown in FIG. 4D may be respectively filled with third material layers 105 and 205. The third material layers 105 and 205 may include at least one of tungsten and titanium nitride (TiN). The third material layers 105 and 205 may surround the upper vertical channels 239, the dummy vertical channel 139′, and the lower vertical channels 139. Accordingly, a first gate stack structure 190 and a second gate stack structure 290 may be formed.

The slit 301 and the trench T may be filled with an insulating material. Accordingly, a first insulating structure 310A inside the slit 301 and a second select line isolation structure 310B inside the trench T may be formed.

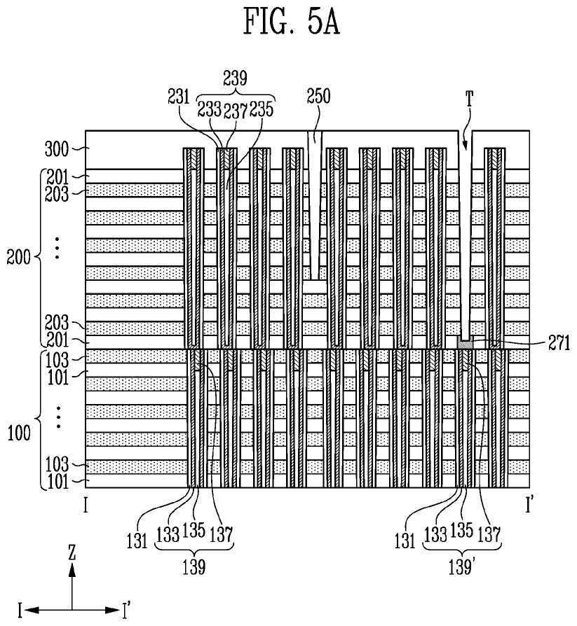

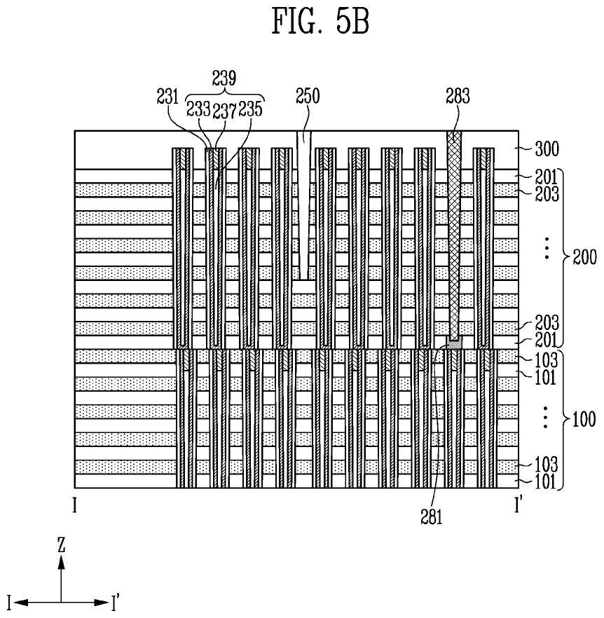

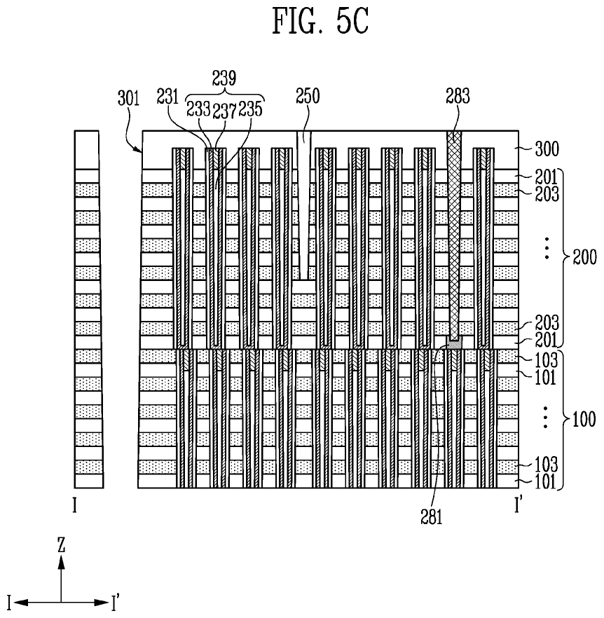

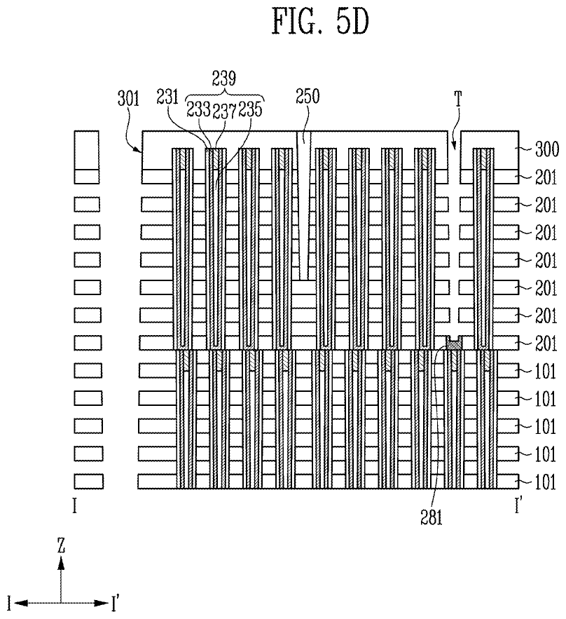

FIGS. 5A to 5D are sectional views illustrating a manufacturing method of a semiconductor memory device in accordance with an embodiment of the present disclosure, FIGS. 5A to 5D are process sectional views taken along the line shown in FIG. 2. Hereinafter, overlapping descriptions of process identical to the processes described with reference to FIGS. 4A to 4E will be omitted.

Referring to FIG. 5A, a first stack structure 100 may be formed, in which first material layers 101 and second material layers 103 are alternately stacked in the third direction Z. Lower memory layers 131, lower vertical channels 139, and a dummy vertical channel 139′ may be formed, which penetrate the first stack structure 100.

A second stack structure 200 in which first material layers 201 and second material layers 203 are alternately stacked in a vertical direction may be formed on the first stack structure 100. A preliminary layer 271 may be buried in a lowermost first material layer 201 among the first material layers 201 of the second stack structure 200. The preliminary layer 271 may be formed of a material having an etch rate different from etch rates of the first material layers 201 and the second material layers 203. In an embodiment, the preliminary layer 271 may include doped silicon. The preliminary layer 271 may overlap with the dummy vertical channel 139′.

Upper vertical channels 239 may be formed, which penetrate the second tack structure 200.

An upper insulating layer 300 may be formed, which covers the second stack structure 200 and the upper vertical channels 239.

A first select line isolation structure 250 may be formed, which penetrates portions of the upper insulating layer 300 and the second stack structure 200.

Subsequently, a trench T may be formed, which penetrates the upper insulating layer 300 and the second stack structure 200. The trench T may overlap with the dummy vertical channel 139′ and the preliminary layer 271, An etching process for forming the trench T may be stopped when the preliminary layer 271 is exposed.

Referring to FIG. 5B, the preliminary layer 271 exposed by the trench T shown in FIG. 5A may be oxidized. Accordingly, an oxide layer 281 may be formed.

Subsequently, the trench T shown in FIG. 5A may be filled with a sacrificial layer 283. The sacrificial layer 283 may be configured with a material having an etch rate different from etch rates of the first stack structure 100, the second stack structure 200, and the first select line isolation structure 250. In an embodiment, the sacrificial layer 283 may include at least one of tungsten, carbon, and titanium nitride (TiN).

Referring to FIG. 5C, a slit 301 may be formed. The slit 301 may penetrate the upper insulating layer 300, the second stack structure 200, and the first stack structure 100.

Referring to FIG. 5D, the trench T may be opened by selectively removing the sacrificial layer 283 shown in FIG. 5C, Subsequently, like FIG. 4D, the second material layers 103 and 203 in the first stack structure 100 and the second stack structure 200, which are shown in FIG. 5C, may be selectively removed through the slit 301 and the trench T, Subsequently, the same sequent process as FIG. 4E may be performed.

FIGS. 6A to 6I are sectional views illustrating a manufacturing method of a semiconductor memory device in accordance with an embodiment of the present disclosure. FIGS. 6A to 6I are process sectional views taken along the line shown in FIG. 2. Hereinafter, overlapping descriptions of process identical to the processes described with reference to FIGS. 4A to 4E will be omitted.

Referring to FIG. 6A, a first stack structure 100 may be formed, which is penetrated by lower memory layers 131, lower vertical channels 139, and a dummy vertical channel 139′. In an embodiment, an uppermost portion of the first stack structure 100 may include a second material layer 103.

Hereinafter, subsequent processes will be described based on sectional views shown in FIGS. 6B to 6D, which correspond to an enlarged region of region A shown in FIG. 6A.

Referring to FIG. 6B, a process of forming the lower memory layer 131 may include a process of stacking a blocking insulating layer 131a, a data storage layer 131b, and a tunnel insulating layer 131c on a sidewall of a channel hole.

The data storage layer 131b may be formed of a material layer capable of storing data changed using Fowler-Nordheim tunneling. To this end, the data storage layer 131b may be formed of various materials. For example, the data storage layer 131b may be formed as a nitride layer capable of trapping charges. However; the present disclosure is not limited thereto, and the data storage layer 131b may include silicon, a phase change material, a nano dot, and the like. The blocking insulating layer 131a may include an oxide layer capable of blocking movement of charges. The tunnel insulating layer 131c may be formed as a silicon oxide layer through which charges can tunnel. The lower memory layer 131 including the blocking insulating layer 131a, the data storage layer 131b, and the tunnel insulating layer 131c and the lower vertical channel structure 139 or the dummy vertical channel structure (139′ shown in FIG. 6A), each of which includes a channel layer 133, a core pillar 135, and a capping pattern 137, may penetrate an uppermost second material layer 103′.

Referring to FIG. 6C, the uppermost second material layer 103′ shown in FIG. 6B may be removed. In an embodiment, when the data storage layer 131b is formed as a nitride layer, a portion of the data storage layer 131b may be etched in the process of removing the uppermost second material layer 103′.

Referring to FIG. 6D, regions in which the uppermost second material layer 103′ and the data storage layer 131b are removed may be respectively filled with a first insulating layer 171A and a second insulating layer 171B. The first insulating layer 171A and the second insulating layer 1713 may include the same material as a first material layer 101. In an embodiment, the first insulating layer 171A and the second insulating layer 1713 may include a silicon oxide layer.

Referring to FIG. 6E, after the first insulating layer 171A is formed at the uppermost portion of the first stack structure 100, a second stack structure 200 may be formed.

The second stack structure 200 may be formed by alternately stacking first material layers 201 and second material layers 203 on the first stack structure 100. Subsequently, upper memory layers 231 and upper vertical channels 239 may be formed, which penetrate the second stack structure 200.

The process of forming the upper memory layer 231 may include a process of stacking a blocking insulating layer; a data storage layer, and a tunnel insulating layer along a surface of a channel hole penetrating the second stack structure 200 and a process of removing a portion of each of the blocking insulating layer, the data storage layer; and the tunnel insulating layer such that the lower vertical channel structure 139 is exposed through a bottom surface of the channel hole. The upper memory layer 231 may be configured with the blocking insulating layer, the data storage layer, and the tunnel insulating layer, which remain on a sidewall of the channel hole. During an etching process for removing a portion of each of the blocking insulating layer, the data storage layer; and the tunnel insulating layer to expose the lower vertical channel structure 139, the data storage layer 131b of the lower memory layer 131 may be protected from the etching process by the second insulating layer 171B.

After the upper memory layers 231 and the upper vertical channels 239 are formed, an upper insulating layer 300 may be formed, which covers the second stack structure 200 and the upper vertical channels 239.

Subsequently, a first trench T1 and a second trench T2, which have different widths, may be formed by etching the upper insulating layer 300 and the second stack structure 200. A first width W1 of the first trench T1 may be formed narrower than a second width W2 of the second trench T2. When the first trench T1 and the second trench T2 are simultaneously formed, the second trench T2 having a relatively wide width may be formed deeper than the first trench T1. The second trench T2 may overlap with the dummy vertical channel 139′. The second trench T2 may be formed to a depth to which the dummy vertical channel 139′ is exposed. The first trench T1 may be disposed at both sides of the second trench T2, and extend between the upper vertical channels 239.

Subsequently, an etch stop layer 107 may be formed by oxidizing an upper portion of the dummy vertical channel 139′ through the second trench T2. However, the embodiment of the present disclosure is not limited thereto, and the process of forming the etch stop layer 107 may be omitted.

Referring to FIG. 6F, a first preliminary select line isolation structure 270A and a second preliminary select line isolation structure 2708 may be respectively formed inside the first trench T1 and the second trench T2, which are shown in FIG. 6E. The second preliminary select line isolation structure 2708 may be connected to the etch stop layer 107.

The first and second preliminary select line isolation structures 270A and 2708 may be configured with a material having an etch rate different from etch rates of the first stack structure 100 and the second stack structure 200. In an embodiment, the first and second preliminary select line isolation structures 270A and 2708 may include at least one of tungsten, carbon, and titanium nitride (TiN).

Referring to FIGS. 6G and 6H, a slit 301 may be formed. The slit 301 may penetrate the upper insulating layer 300, the second stack structure 200, and the first stack structure 100. Subsequently, the first trench T1 and the second trench T2 may be opened by removing the first and second preliminary select line isolation structures 270A and 2708. An etching process for removing the first and second preliminary select line isolation structures 270A and 2708 may be stopped when the etch stop layer 107 is exposed.

Referring to FIG. 6I, the second material layers 103 and 203 in the first stack structure 100 and the second stack structure 200, which are shown in FIG. 6H, may be selectively removed through the first and second trenches T1 and T2, During the process of selectively removing the second material layers 103 and 203, the lower memory layer 131 surrounding the dummy vertical channel 139′ may be protected by the etch stop layer 107.

Subsequently, third material layers 105 and 205 configured with a conductive material may be formed between the first material layers 101 and 201 adjacent to each other in the third direction Z as shown in FIG. 4E by performing the subsequent process as FIG. 4E, Subsequently, an insulating material may be formed inside the first and second trenches T1 and T2 and the slit 301. The insulating material filling the first trench T1 may be used as the first select line isolation structure DSM1 shown in FIGS. 2 and 3, and the insulating material filling the second trench T2 may be used as the second select line isolation structure DSM2 shown in FIGS. 2 and 3.

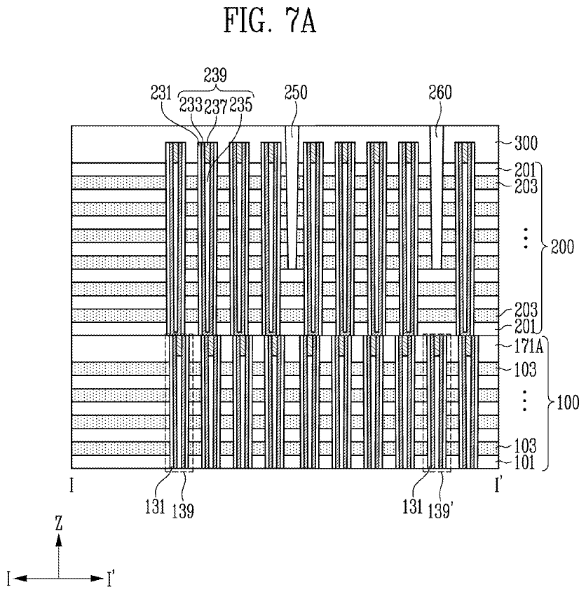

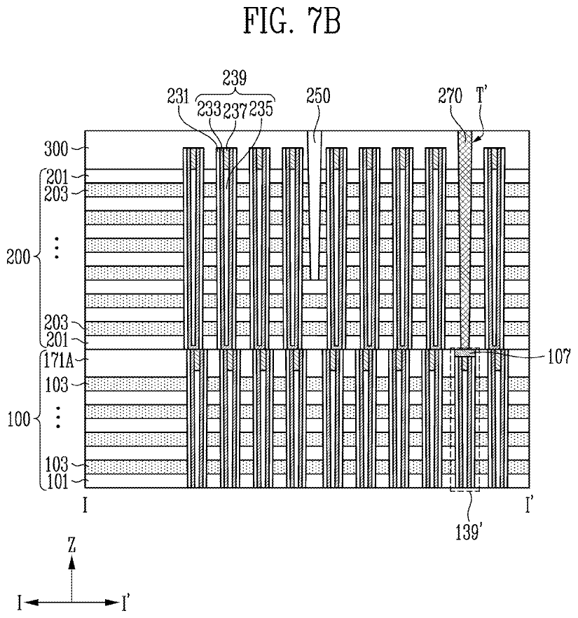

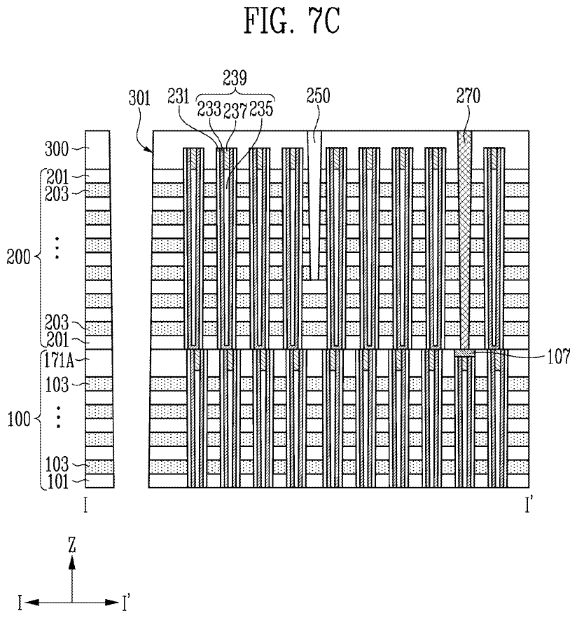

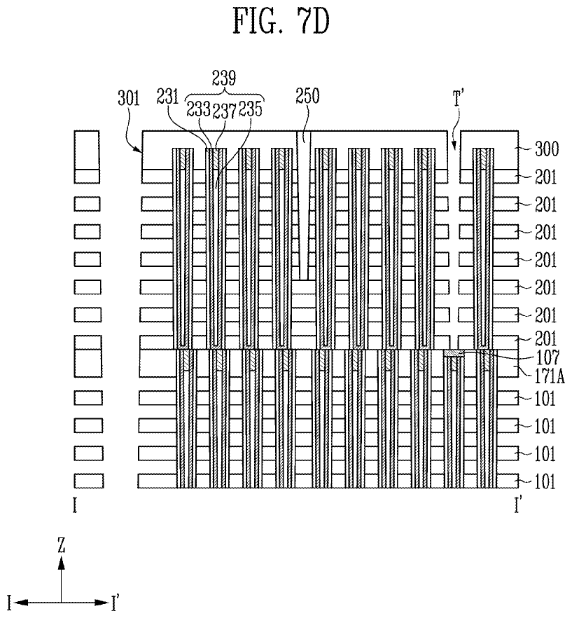

FIGS. 7A to 7D are sectional views illustrating a manufacturing method of a semiconductor memory device in accordance with an embodiment of the present disclosure. FIGS. 7A to 7D are process sectional views taken along the line shown in FIG. 2.

Referring to FIG. 7A, by using the processes described with reference to FIGS. 6A to 6I, a first stack structure 100 including first material layers 101, second material layers 103, and a first insulating layer 171A, lower memory layers 131, lower vertical channels 139, and a dummy vertical channel 139′, which penetrate the first stack structure 100, a second stack structure 200 including first material layers 201 and second material layers 203, upper memory layers 231 and upper vertical channels 239, which penetrate the second stack structure 200, and an upper insulating layer 300 may be formed.

Subsequently, a first select line isolation structure 250 and a first preliminary select line isolation structure 260 may be formed, which penetrate the upper insulating layer 300 and portions of the second stack structure 200. The first preliminary select line isolation structure 260 may be simultaneously formed with the first select line isolation structure 250, and be formed to have a depth and a width, which are substantially equal to a depth and a width of the first select line isolation structure 250. The first select line isolation structure 250 and the first preliminary select line isolation structure 260 may be formed of an insulating material. The first preliminary select line isolation structure 260 may overlap with the dummy vertical channel 139′, and be disposed at a position spaced apart from the dummy vertical channel 139′ in the third direction Z, The first select line isolation structure 250 may be disposed at both sides of the first preliminary select line isolation structure 260, and be disposed between the upper vertical channels 239.

Referring to FIG. 7B, the first preliminary select line isolation structure 260 shown in FIG. 7A may be removed by using a mask pattern (not shown) as an etch barrier. Subsequently, a lower portion of the second stack structure 200 may be etched through a region in which the first preliminary select line isolation structure is removed. Accordingly, a trench T′ penetrating the second stack structure 200 may be defined. Subsequently, an etch stop layer 107 may be formed by oxidizing a portion of the dummy vertical channel 139′, which is exposed through the trench T′. Subsequently, a second preliminary select line isolation structure 270 may be formed inside the trench T′. The second preliminary select line isolation structure 270 may be configured with a material having an etch rate different from etch rates of the first stack structure 100 and the second stack structure 200. In an embodiment, the second preliminary select line isolation structure 270 may include at least one of tungsten, carbon, and titanium nitride (Till). After, the second preliminary select line isolation structure 270 is formed, the mask pattern may be removed.

The second preliminary select line isolation structure 270 may extend even to a level lower than a level of the first select line isolation structure 250. The second preliminary select line isolation structure 270 may be in contact with the etch stop layer 107.

Referring to FIG. 7C, a slit 301 may be formed. The slit 301 may penetrate the upper insulating layer 300, the second stack structure 200, and the first stack structure 100.

Referring to FIG. 7D, the second preliminary select line isolation structure 270 shown in FIG. 7C may be removed. Accordingly, the trench T′ may be opened. The etch stop layer 107 may be exposed.

Subsequently, the second material layers 130 and 203 of the first stack structure 100 and the second stack structure 200, which are shown in FIG. 7C, may be selectively removed through the slit 301 and the trench T′, Subsequently, third material layers 105 and 205 configured with a conductive material may be formed between the first material layers 101 and 201 adjacent to each other in the third direction Z as shown in FIG. 4E by performing the same subsequent process as FIG. 4E. Subsequently, an insulating material may be formed inside the trench T′ and the slit 301. The insulating material filling the trench T′ may be used as the second select line isolation structure DSM2 shown in FIGS. 2 and 3. A width of the insulating material filling the trench T′ and used as the select line isolation structure DSM2 shown in FIGS. 2 and 3 may not to be exceed a width of the first select line isolation structure 250. In an embodiment, the width of the select line isolation structure DSM2 in FIGS. 2 and 3 substantially the same as the width of the first selection line isolation structure 250.

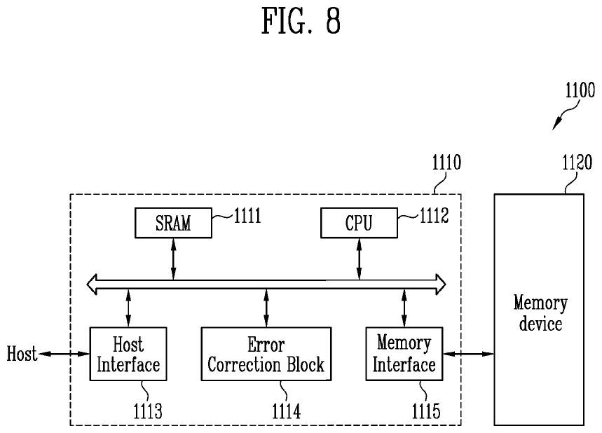

FIG. 8 is a block diagram illustrating a configuration of a memory system in accordance with an embodiment of the present disclosure.

Referring to FIG. 8, the memory system 1100 includes a memory device 1120 and a memory controller 1110.

The memory device 1120 may be a multi-chip package configured with a plurality of flash memory chips.

The memory controller 1110 controls the memory device 1120, and may include a Static Random Access Memory (SRAM) 1111, a Central Processing Unit (CPU) 1112, a host interface 1113, an error correction block 1114, and a memory interface 1115. The SRAM 1111 is used as an operation memory of the CPU 1112, the CPU 1112 performs overall control operations for data exchange of the memory controller 1110, and the host interface 1113 includes a data exchange protocol for a host connected with the memory system 1100. The error correction block 1114 detects an error included in a data read from the memory device 1120, and corrects the detected error. The memory interface 1115 interfaces with the memory device 1120. The memory controller 1110 may further include a Read Only Memory (ROM) for storing code data for interfacing with the host, and the like.

The memory system 1100 configured as described above may be a memory card or a Solid State Disk (SSD), in which the memory device 1120 is combined with the controller 1110. For example, when the memory system 1100 is an SSD, the memory controller 1100 may communicated with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer System Interface (SCSI) protocol, an Enhanced Small Disk Interface (ESDI) protocol, and an Integrated Drive Electronics (IDE) protocol.

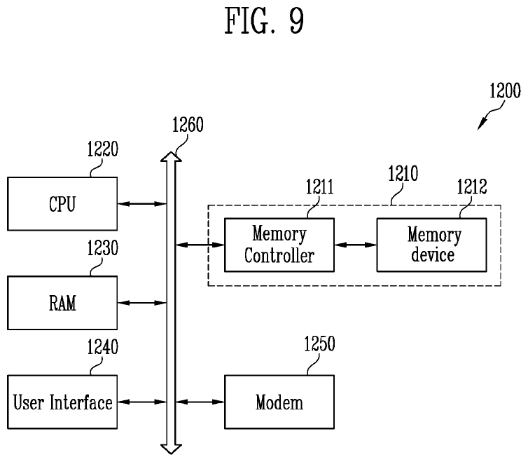

FIG. 9 is a block diagram illustrating a configuration of a computing system in accordance with an embodiment of the present disclosure.

Referring to FIG. 9, the computing system 1200 may include a CPU 1220, a random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, an image processor, a mobile D-RAM, and the like may be further included.

The memory system 1210 may be configured with a memory device 1212 and a memory controller 1211.

The memory controller 1211 may be configured identically to the memory controller 1110 described above with reference to FIG. 8.

In accordance with the present disclosure, in an embodiment, a conductive layer surrounding a plurality of vertical channels can be isolated into select lines through a first select line isolation structure and a second select line isolation structure, which are disposed between the plurality of vertical channels.

While the present disclosure has been shown and described with reference to certain examples of embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described examples of embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the examples of embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A semiconductor memory device comprising:
a first gate stack structure including first interlayer insulating layers and first conductive layers, which are alternately stacked in a vertical direction;
a dummy vertical channel penetrating the first gate stack structure;
lower vertical channels penetrating the first gate stack structure at both sides of the dummy vertical channel;
a second gate stack structure including second interlayer insulating layers and second conductive layers, which are alternately stacked in the vertical direction on the first gate stack structure;
a first select line isolation structure partially penetrating the second gate stack structure;
upper vertical channels directly connected to the lower vertical channels; and
a second select line isolation structure overlapping with the dummy vertical channel in the vertical direction, the second select line isolation structure partially penetrating the second gate stack structure.

2. The semiconductor memory device of claim 1, wherein the first select line isolation structure is disposed between the upper vertical channels at both sides of the second select line isolation structure.

3. The semiconductor memory device of claim 1, wherein the first select line isolation structure does not overlap with the dummy vertical channel.

4. The semiconductor memory device of claim 1, wherein a width of the second select line isolation structure doesn't exceed a width of the first select line isolation structure.

5. The semiconductor memory device of claim 1, wherein a first width of the first select line isolation structure is narrower than a second width of the second select line isolation structure.

6. The semiconductor memory device of claim 5, wherein a length of the second select line isolation structure is longer than a length of the first select line isolation structure.

7. The semiconductor memory device of claim 5, wherein the second select line isolation structure extends to completely penetrate the second gate stack structure.

8. The semiconductor memory device of claim 1, wherein at least one of the second conductive layers of the second gate stack structure extends between the first select line isolation structure and the first gate stack structure.

9. The semiconductor memory device of claim 1, wherein at least one of the second conductive layers of the second gate stack structure extends between the second select line isolation structure and the dummy vertical channel.

10. The semiconductor memory device of claim 1, further comprising an etch stop layer disposed on the dummy vertical channel, wherein the dummy vertical channel partially penetrates the first gate stack structure.

11. A semiconductor memory device comprising:
a first gate stack structure including first interlayer insulating layers and first conductive layers, which are alternately stacked in a vertical direction;
a dummy vertical channel penetrating the first gate stack structure;
lower vertical channels each completely penetrating the first gate stack structure;
an etch stop layer disposed over the dummy vertical channel and directly on the dummy vertical channel;
a lower memory layer surrounding the lower vertical channels;
a second gate stack structure on the first gate stack structure, the second gate stack structure including second interlayer insulating layers and second conductive layers alternately stacked with each other in the vertical direction;
an upper insulating layer disposed on the second gate stack structure;
a first select line isolation structure completely penetrating the upper insulating layer and partially penetrating the second gate stack structure; and
a second select line isolation structure being in direct contact with the etch stop layer.

12. The semiconductor memory device of claim 11, wherein the lower memory layer includes a blocking insulating layer formed along a sidewall of the lower vertical channel, a data storage layer between the blocking insulating layer and the lower vertical channel, and a tunnel insulating layer between the data storage layer and the lower vertical channel.

13. The semiconductor memory device of claim 12, further comprising an insulating layer disposed between the blocking insulating layer and the tunnel insulating layer, the insulating layer covering the data storage layer.

14. The semiconductor memory device of claim 11, wherein a second width of the second select line isolation structure is wider than a first width of the first select line isolation structure, and
wherein a second length of the second select line isolation structure is longer than a first length of the first select line isolation structure.

15. The semiconductor memory device of claim 11, wherein a width of the second select line isolation structure doesn't exceed a width of the first select line isolation structure.

16. The semiconductor memory device of claim 11, wherein at least one of the second conductive layers of the second gate stack structure extends between the first select line isolation structure and the first gate stack structure.

17. A method of manufacturing a semiconductor memory device, the method comprising:
forming a first stack structure;
forming a dummy vertical channel penetrating the first gate stack structure;
forming lower vertical channels each completely penetrating the first stack structure;
forming a second stack structure on the first stack structure;
forming first and second select line isolation structures partially penetrating the second stack structure; and
forming upper vertical channels directly connected to the lower vertical channels wherein the second select line isolation structure is formed longer than the first select line isolation structure, and
wherein each of the first stack structure and the second stack structure includes a plurality of first material layers and a plurality of second material layers, which are alternately stacked in a vertical direction.

18. The method of claim 17, wherein the forming of the first and second select line isolation structures includes:
forming the first select line isolation structure;
forming a preliminary select line isolation structure overlapping the dummy vertical channel, while the first select line isolation structure is formed;
forming a slit completely penetrating the first stack structure and the second stack structure;
opening a trench by removing the preliminary select line isolation structure; and
forming the second select line isolation structure by filling the trench with an insulating material.

19. The method of claim 18, further comprising replacing the plurality of second material layers with a plurality of third material layers through the slit and the trench, before the second select line isolation structure is formed after the first select line isolation structure is formed.

20. The method of claim 18, wherein the first select line isolation structure and the preliminary select line isolation structure are formed before the upper vertical channels are formed.

21. The method of claim 17, wherein the forming of the first and second select line isolation structures includes:
forming the first select line isolation structure;
forming a trench overlapping with the dummy vertical channel, the trench penetrating the second stack structure;
forming a preliminary select line isolation structure inside the trench;
forming a slit completely penetrating the first stack structure and the second stack structure;
opening the trench by removing the preliminary select line isolation structure; and
forming the second select line isolation structure by filling the trench with an insulating material.

22. The method of claim 21, further comprising replacing the plurality of second material layers with a plurality of third material layers through the slit and the trench, before the second select line isolation structure is formed after the first select line isolation structure is formed.

23. The method of claim 21, wherein the first select line isolation structure and the trench are formed after the upper vertical channels are formed.

24. The method of claim 21, further comprising:
forming a preliminary layer overlapping with the dummy channel structure in a lowermost layer of the second stack structure;
forming the trench such that the preliminary layer is exposed; and
oxidizing the preliminary layer through the trench.

25. The method of claim 17, wherein the forming of the first and second select line isolation structures includes:
forming a first trench by etching a portion of the second stack structure;
forming a second trench overlapping with the dummy vertical channel, while the first trench is formed;
forming a first preliminary select line isolation structure and a second preliminary select line isolation structure respectively inside the first trench and the second trench;
forming a slit completely penetrating the first stack structure and the second stack structure;
opening the first trench and the second trench by removing the first preliminary select line isolation structure and a second preliminary select line isolation structure; and
forming the first select line isolation structure and the second select line isolation structure by filling the first trench and the second trench with an insulating material.

26. The method of claim 25, further replacing the plurality of second material layers with a plurality of third material layers through the first trench, the second trench, and the slit.

27. The method of claim 17, wherein the forming of the first and second select line isolation structures includes:
forming the first select line isolation structure;
forming a first preliminary select line isolation structure overlapping with the dummy vertical channel, while the first select line isolation structure is formed;
removing the first preliminary select line isolation structure;
forming a trench exposing the dummy vertical channel by etching a lower portion of the second stack structure through a region in which the first preliminary select line isolation structure is removed;
forming an etch stop layer by oxidizing a portion of the dummy vertical channel;
forming a second preliminary select line isolation structure disposed on the etch stop layer, the second preliminary select line isolation structure being disposed inside the trench;
forming a slit completely penetrating the first stack structure and the second stack structure;
opening the trench by removing the second preliminary select line isolation structure; and
forming the second select line isolation structure by filling the trench with an insulating material.

28. The method of claim 27, further comprising replacing the plurality of second material layers with a plurality of third material layers through the slit and the trench, before the second select line isolation structure is formed after the first select line isolation structure is formed.

29. A method of manufacturing a semiconductor memory device, the method comprising:
forming a first stack structure;
forming channel holes completely penetrating the first stack structure;
forming lower memory layers along surfaces of the channel holes;
forming a dummy vertical channel and lower vertical channels inside the channel holes;
forming an insulating layer inside each of the lower memory layers;
forming a second stack structure on the first stack structure;
forming upper vertical channels directly connected to the lower vertical channels; and
forming a first select line isolation structure and a second select line isolation structure, which partially penetrate the second stack structure,
wherein each of the lower memory layers includes a blocking insulating layer extending along a sidewall of a channel hole corresponding thereto among the channel holes, a data storage layer extending along a sidewall of the blocking insulating layer, and a tunnel insulating layer extending along a sidewall of the data storage layer, and
wherein the insulating layer is disposed between the blocking insulating layer and the data storage layer, and covers the data storage layer.
